(19) United States
(12) Patent Application Publication
(10) Pub. No.: US 2026/0113872 A1
(43) Pub. Date: Apr. 23, 2026

(54) DATA CENTER COOLING SYSTEM

(71) Applicant: Equinix, Inc., Redwood City, CA (US)

(72) Inventors: Douglas James Asay, San Jose, CA (US); Gregory Metcalf, San Francisco, CA (US)

(21) Appl. No.: 18/922,165

(22) Filed: Oct. 21, 2024

(51) Int. Cl. H05K 7/20

(52) U.S. Cl. CPC H05K 7/20263; H05K 7/20272; H05K 7/20745; H05K 7/20781

(57) ABSTRACT

A data center cooling system includes a technical fluid system, a liquid cooling system, and an air cooling system. The technical fluid system includes a primary heat exchanger (PHEX), a heat rejection unit, and a technical fluid circuit. The PHEX is configured to transfer heat from a technical fluid to a cooling fluid and hydraulically isolate the technical fluid from the cooling fluid. The technical fluid circuit includes one or more pumps configured to circulate the cooling fluid between the PHEX and the heat rejection unit. The liquid cooling system includes one or more liquid cooling connectors fluidically coupled to the PHEX and configured to fluidically couple to a server heat exchanger (SHEX). The air cooling system includes one or more computer room air conditioning (CRAC) units fluidically coupled to the PHEX and configured to cool supply air.

### TECHNICAL FIELD

This disclosure relates to cooling systems, and more specifically, to cooling systems for data centers.

### BACKGROUND

Computing devices, such as servers and networking equipment, may be installed in cabinets that provide structure, security, and/or connectivity to the computing devices. A data hall may provide both forced air cooling and liquid cooling to the cabinets. To provide forced air cooling to the cabinets, one or more cooling and circulation devices circulate cooler supply air to the data hall, draw warmer return air back to the cooling devices, and condition (e.g., cool and filter) the warmer return air. To increase cooling to the cabinets, the cooling and circulation systems may increase the flow or decrease the temperature of the supply air to the data hall. To provide liquid cooling to the cabinets, liquid cooling lines discharge a cooling liquid to heat exchangers on or within the cabinets, such as in a rear door of the cabinet or directly on computing devices within the cabinets. While forced air cooling may provide relatively uniform bulk cooling to the cabinets, liquid cooling may provide individualized cooling to particular cabinets or groups of cabinets. For example, cooling distribution units (CDU) may supply a technical fluid to cabinets at a specific temperature to facilitate cooling.

### SUMMARY

This disclosure describes cooling systems for a data center that directly supply technical fluid to both bulk air cooling systems and localized liquid cooling systems without the use of intermediate cooling distribution units (CDUs).

A data center cooling system includes a liquid cooling system that cools cabinets via server heat exchangers (SHEX) and an air cooling system that cools cabinets via supply air discharged by computer room air conditioning (CRAC) units. The data center cooling system also includes a technical fluid system having a primary heat exchanger (PHEX) that transfers heat from a technical fluid to a cooling fluid, a heat rejection unit that rejects heat from the cooling fluid, and a technical fluid circuit that distributes the technical fluid to the liquid and air cooling systems for cooling the cabinets.

Rather than supply the cooling fluid to separate cooling distribution units that then supply a technical fluid to the SHEXs, the technical fluid circuit distributes the technical fluid directly to both the SHEXs and CRACs. The technical fluid circuit may supply technical fluid that is substantially single phase, thereby eliminating compression of the technical fluid and reducing power consumption for additional cooling of the technical fluid. Elimination of the intermediate CDU between the PHEX and the heat exchangers that provide cooling to the cabinets may reduce weight, size, power consumption, and complexity of the technical fluid system. Portions of the data center cooling system, such as the PHEX, heat rejection unit, and pumps of the technical fluid system, can be deployed in a modular design to selectively add cooling capacity that can be shared among heat loads. In these various ways, data center cooling systems that directly supply technical fluid to data hall or cabinet-level heat exchangers may be more efficient, cost-effective, and reliable that data center cooling systems that utilize CDUs.

In some examples, a technical fluid system includes a technical fluid circuit, a primary heat exchanger (PHEX), a heat rejection unit, and a cooling fluid circuit. The technical fluid circuit includes one or more technical fluid pumps configured to deliver a technical fluid to a liquid cooling system and an air cooling system. The PHEX is configured to transfer heat from the technical fluid to a cooling fluid. The heat rejection unit is configured to remove heat from the cooling fluid. The cooling fluid circuit includes one or more cooling fluid pumps configured to circulate the cooling fluid between the PHEX and the heat rejection unit.

In some examples, a data center cooling system includes a liquid cooling system, an air cooling system, and one or more technical fluid systems fluidically coupled to the liquid cooling system and the air cooling system. The liquid cooling system includes one or more liquid cooling connectors configured to fluidically couple to a server heat exchanger (SHEX) of a cabinet. The air cooling system includes one or more computer room air conditioning (CRAC) units configured to cool supply air. Each technical fluid system includes a technical fluid circuit, a primary heat exchanger (PHEX), a heat rejection unit, and a cooling fluid circuit. The technical fluid circuit includes one or more technical fluid pumps configured to deliver the technical fluid to the liquid cooling system and the air cooling system. The PHEX is configured to transfer heat from the technical fluid to a cooling fluid. The heat rejection unit is configured to remove heat from the cooling fluid. The cooling fluid circuit includes one or more cooling fluid pumps configured to circulate the cooling fluid between the PHEX and the heat rejection unit.

In some examples, a method for cooling cabinets of a data center includes delivering, by one or more technical fluid systems, a technical fluid to one or more server heat exchangers (SHEX) of a liquid cooling system and one or more computer room air conditioning (CRAC) units of an air cooling system. Such delivery is performed by at least, for each technical fluid system, circulating, by one or more technical fluid pumps of a technical fluid circuit, the technical fluid between a primary heat exchanger (PHEX) and each of the liquid cooling system and the air cooling system to absorb heat from the one or more SHEXs and the one or more CRAC units, and circulating, by one or more cooling fluid pumps of a cooling fluid circuit, a cooling fluid between the PHEX and a heat rejection unit to transfer heat from the technical fluid to the cooling fluid and remove the heat from the cooling fluid.

### BRIEF DESCRIPTION OF THE DRAWINGS

FIG. 1 is a conceptual block diagram illustrating a data center cooling system for cooling cabinets of a data hall.

FIG. 2 is a schematic diagram illustrating an example data center cooling system for cooling cabinets of a data hall.

FIG. 3 is a conceptual side view diagram illustrating an example modular unit of a data center cooling system.

FIG. 4 is a block diagram illustrating an example controller configured to control cooling for a data center cooling system.

FIG. 5 is a flow diagram of an example technique for cooling cabinets of a data hall using a data center cooling system.

### DETAILED DESCRIPTION

Effective cooling systems ensure reliable and continuous operation of equipment in a data center, thereby preventing potential downtime and data loss. To provide liquid cooling to this equipment, a data center cooling system may supply a cooling fluid, such as chilled water, to a cooling distribution unit (CDU). A CDU is a commercial product for direct-to-chip liquid cooling applications that uses a heat exchanger and one or more pumps to hydraulically separate a cooling fluid from a technical fluid used to cool the equipment. The CDU delivers the technical fluid to equipment heat exchangers at a specific temperature to remove heat, and transfers the removed heat to the cooling fluid.

Whenever a CDU is utilized, the temperature at which the technical fluid is supplied becomes higher than the temperature at which the cooling fluid is supplied by several degrees (i.e., the approach temperature). The use of CDUs introduces inefficiencies due to this increased supply temperature of the technical fluid and the additional pumping power required to flow cooling and technical fluids through the heat exchanger of the CDU. To address this issue, smaller CDUs are often deployed for liquid cooling. In addition to CDUs, there may be other heat exchanger components in a cooling system, such as cooling coils, chiller evaporators/condensers, and economizers, that may introduce approaches that increase the temperature of the cooling fluid at its point of use and increase the energy required to produce the specified final temperature of the cooling fluid. To deliver technical fluid at a sufficiently low temperature, a CDU may include compression equipment for delivering the technical fluid at lower temperatures, which not only increases the overall system complexity but also incurs additional energy costs. CDUs may not be completely integrated with the heat rejection plant into a single, modular package, which can lead to operational inefficiencies and increased maintenance requirements.

Data center cooling systems described herein directly supply technical fluid to both bulk air cooling systems and localized liquid cooling systems without the use of intermediate cooling distribution units (CDUs). A data center cooling system includes a liquid cooling system that cools cabinets via server heat exchangers (SHEX) and an air cooling system that cools cabinets via supply air discharged by computer room air conditioning (CRAC) units. The data center cooling system also includes a technical fluid system having a primary heat exchanger (PHEX) that transfers heat from a technical fluid to a cooling fluid, a heat rejection unit that rejects heat from the cooling fluid, and a technical fluid circuit that distributes the technical fluid for cooling the cabinets.

Rather than supply the technical fluid to separate CDUs that then supply another technical fluid to the SHEXs and CRACs, the technical fluid circuit distributes the technical fluid directly to the SHEXs and CRACs. The technical fluid circuit may supply technical fluid, such as a mixture of water and propylene glycol, that is substantially single phase and relatively hot, thereby eliminating compression of the technical fluid and reducing power consumption for additional cooling of the technical fluid. Elimination of the intermediate CDU between the PHEX and the heat exchangers that provide cooling to the cabinets may reduce weight, size, power consumption, and complexity of the technical fluid system, such as by providing lower temperatures of the technical fluid and reduces energy for delivering the technical fluid. The technical fluid system can be deployed in a modular design to selectively add cooling capacity that can be shared among cooling loads. For example, a modular unit may be designed for a particularly cooling capacity, such as a 2500 kW equipment load, which can provide flexibility and efficiency for meeting different cooling needs.

In these various ways, data center cooling systems that directly supply technical fluid to data hall or cabinet-level heat exchangers may be more efficient, cost-effective, and reliable that data center cooling systems that utilize CDUs. The data center cooling systems may be particularly useful for large-scale data centers that require efficient and effective cooling solutions for their IT equipment loads, as lower technical fluid temperatures for liquid cooling and reduced pumping energy may significantly enhance the efficiency and effectiveness of data center cooling systems, thereby contributing to the overall performance and reliability of data centers. Additionally, cooling systems described herein may be used in industries other than data centers that require efficient cooling solutions, such as manufacturing plants, research facilities, and telecommunications hubs. For example, the modular design of the cooling systems may permit easy integration and customization according to the specific cooling needs of different facilities, making it a versatile and practical solution for various cooling applications.

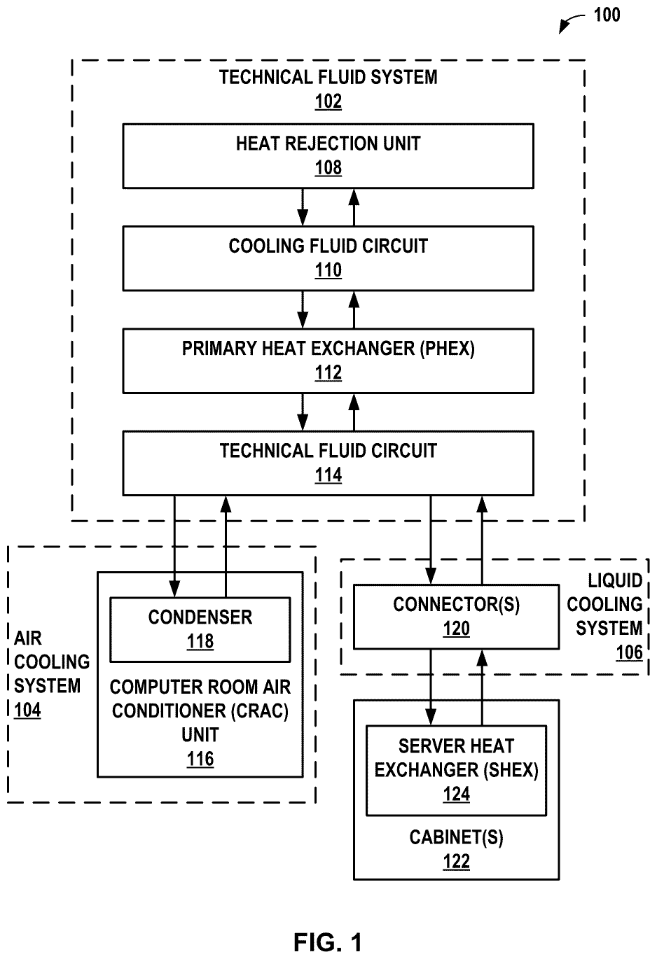

FIG. 1 is a conceptual block diagram illustrating a data center cooling system 100 for cooling cabinets 122 of a data hall. To provide cooling to cabinets 122, data center cooling system 100 includes an air cooling system 104 and a liquid cooling system 106.

Air cooling system 104 is configured to provide bulk air cooling to cabinets 122 by discharging cooled supply air. Air cooling system 104 includes one or more computer room air conditioning (CRAC) units fluidically coupled to technical fluid circuit 114. Each CRAC unit 116 is configured to cool supply air and deliver the supply air to cabinets 122. Each CRAC unit 116 includes a condenser 118 configured to receive the technical fluid from technical fluid circuit 114, receive refrigerant from evaporator coils, and transfer heat from refrigerant to the technical fluid to condense the refrigerant.

For cabinets 122 generating more heat than may be removed by the cooled supply air, liquid cooling system 106 is configured to provide localized liquid cooling to cabinets 122 by directly supplying cabinets 122 with the technical fluid, rather than supply cabinets 122 with a secondary fluid cooled by the technical fluid via a cooling distribution unit. Liquid cooling system 106 includes one or more liquid cooling connectors 120 fluidically coupled to technical fluid circuit 114. Each connector 120 is configured to fluidically couple to a server heat exchanger (SHEX) 124 of respective cabinet 122. SHEX 124 may include any heat exchanger that may be positioned on or within a cabinet 122 including, but not limited to, direct-to-chip heat exchangers, rear-door heat exchangers, immersion cooling heat exchangers, in-row heat exchangers, or another other heat exchangers that may provide convective or conductive cooling to a single cabinet 122.

Data center cooling system 100 includes a technical fluid system 102 configured to deliver a technical fluid to air cooling system 104 and liquid cooling system 106 and condition the technical fluid, including removing absorbed heat using a cooling fluid. Parameters for which the technical fluid may be selected include, but are not limited to, high thermal conductivity, high corrosion inhibition, non-toxicity, compatibility with sealing materials, and low vapor pressure. Technical fluids that may be used include, but are not limited to, glycols (e.g., propylene glycol and ethylene glycol), water (e.g., reverse osmosis or deionized water), glycol-water mixtures, fluorinated fluids, and the like, and may include additives such as corrosion inhibitors or biocides. In some examples, the technical fluid is a mixture of propylene glycol and water, such as 25 weight percent (wt. %) propylene and a balance water. Parameters for which the cooling fluid may be selected include, but are not limited to, high thermal conductivity, high specific heat capacity, low viscosity, low freezing point, high boiling point, and the like. Cooling fluids that may be used include, but are not limited to, water, water-glycol mixtures, brine solutions, and the like.

Technical fluid system 102 includes a heat rejection unit 108, a cooling fluid circuit 110, a primary heat exchanger (PHEX) 112, and a technical fluid circuit 114. Technical fluid circuit 114 is configured to circulate the technical fluid between the technical fluid system 102 and both air cooling system 104 and liquid cooling system 106. Technical fluid circuit 114 includes one or more technical fluid pumps configured to provide a driving force for circulating the technical fluid between the PHEX and each of liquid cooling system 106 and air cooling system 104. While described as circulating technical fluid, technical fluid circuit 114 may be configured to perform other functions, such as filling or draining technical fluid, filtering technical fluid, modifying a chemical composition of the technical fluid, and other conditioning functions.

PHEX 112 is configured to transfer heat from the technical fluid to the cooling fluid. On one side, PHEX 112 receives the heated technical fluid from air cooling system 104 and liquid cooling system 106 via technical fluid circuit 114, removes heat from the technical fluid, and discharges technical fluid at a lower temperature. On an opposite side, PHEX 112 receives the cooling fluid from heat rejection unit 108 via cooling fluid circuit 110, absorbs heat into the cooling fluid, and discharges the cooling fluid at a higher temperature. A temperature gradient between the technical fluid and the cooling fluid drives exchange of the heat between the technical fluid and the cooling fluid. A variety of heat exchangers may be used including, but not limited to, plate heat exchangers, shell and tube heat exchangers, and the like.

Cooling fluid circuit 110 is configured to circulate the cooling fluid between PHEX 112 and heat rejection unit 108. Cooling fluid circuit 110 includes one or more cooling fluid pumps configured to provide a driving force for circulating the cooling fluid between PHEX 112 and heat rejection unit 108. While described as circulating cooling fluid, cooling fluid circuit 110 may be configured to perform other functions, such as filling or draining cooling fluid, filtering cooling fluid, modifying a chemical composition of the cooling fluid, and other conditioning functions.

Heat rejection unit 108 is configured to receive a cooling fluid, remove heat from the cooling fluid, and discharge the cooling fluid at a lower temperature. The removed heat may be discharged to an external environment, such as an atmosphere, or another heat sink. Heat rejection units that may be used include, but are not limited to, cooling towers, including open-and closed-circuit cooling towers; dry coolers, chillers, adiabatic coolers, heat exchangers, and the like. In some examples, heat rejection unit 108 may be a cooling tower. For example, cooling towers may remove heat from the cooling fluid by evaporating a portion of the cooling fluid.

Technical fluid system 102 is configured to replace intermediate CDUs by providing functionality that may otherwise be provided by CDUs, such as hydraulic isolation of the technical fluid and the cooling fluid, pumping of the technical fluid, filtering of the technical fluid, and monitoring of the technical fluid. For example, PHEX 112 may provide hydraulic isolation between the relatively dirty cooling fluid of heat rejection unit 108 and the relatively clean technical fluid.

In operation, technical fluid system 102 delivers the technical fluid to air cooling system 104 and liquid cooling system 106 at a minimum pressure differential between supply to and return from air cooling system 104 and liquid cooling system 106, such that air cooling system 104 and liquid cooling system 106 may receive adequate flow of the technical fluid. A temperature of the technical fluid may be dependent on an amount of heat removed by PHEX 112, which may in turn be dependent on an amount of heat discharged by heat rejection unit 108. In examples in which heat rejection unit 108 is a cooling tower, the temperature of the technical fluid may vary depending on the ambient wet bulb temperature of an environment to which heat is discharged. Supplying technical fluid at a lowest temperature possible based on heat removal by PHEX 112 may enable partial or full free air cooling for CRAC units 116. The temperature of the technical fluid may be sufficiently low and the pressure differential of the technical fluid sufficiently high that condenser 118 removes heat from a refrigerant at a rate that enables CRAC unit 116 discharges supply air at a desired temperature, and SHEX 124 removes heat from cabinets 122 at a rate that maintains cabinets 122 below a desired temperature. For example, technical fluid system 102 may supply a water-glycol mixture as a technical fluid at a temperature less than or equal to about 35° C., such as a temperature in a range between 15° C. to about 35° C. Because the technical fluid is supplied directly to condenser 118 and/or SHEX 124, rather than to a CDU that supplies a different technical fluid to condenser 118 and/or SHEX 124, the temperature of the technical fluid may require less cooling than may otherwise be needed for an additional stage of heat transfer. As a result, the approach temperature may be sufficiently low for heat absorption at both condenser 118 and SHEX 124, but not so low that the technical fluid requires compression.

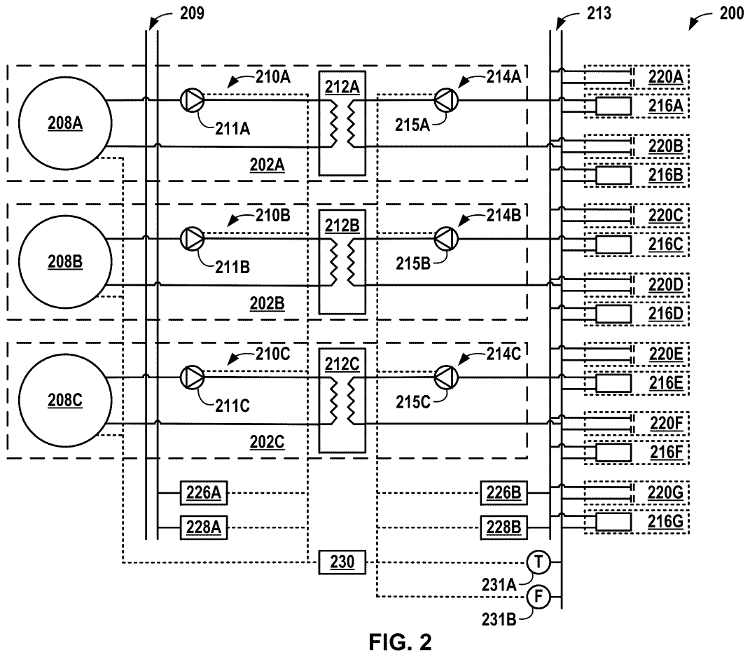

As described above, data center cooling systems described herein may include one or more technical fluid systems that each deliver a particular cooling capacity for various heat loads generated by air and liquid cooling systems. FIG. 2 is a schematic diagram illustrating an example data center cooling system for cooling cabinets of a data hall. Data center cooling system 200 includes an air cooling system and a liquid cooling system that provide cooling to the cabinets (not shown). In the example of FIG. 2, the air cooling system includes seven CRAC units 216A, 216B, 216C, 216D, 216E, 216F, 216G and the liquid cooling system includes seven sets of connectors 220A, 220B, 220C, 220D, 220E, 220F, 220G.

Each CRAC unit 216 is configured to receive technical fluid for cooling supply air and return the heated technical fluid for heat removal. CRAC units 216 are configured to maintain a temperature and humidity level of a data room in a data center to ensure the proper functioning of cabinets and other equipment. Each CRAC unit 216 is configured to draw warm return air from a data room and pass the warm air over evaporator coils. A refrigerant flowing through the evaporator coils absorbs heat from the warm air and evaporates as a low pressure gas, and the cooled return air is discharged back to the data room as supply air. The low pressure refrigerant gas is compressed by a compressor to a higher pressure and temperature, and subsequently enters a condenser. The high-pressure, high-temperature refrigerant gas releases the absorbed heat into the technical fluid as it condenses into a high-pressure liquid. The heated technical fluid is discharged from CRAC unit 216. After releasing its heat in the condenser, the high-pressure liquid refrigerant passes through an expansion valve that reduces the pressure of the refrigerant, cooling it down and converting it back into a low-pressure liquid.

Each set of connectors 220 is configured to deliver technical fluid to heat exchangers on or within cabinets and return the technical fluid for heat removal. Connectors 220 may interface with a liquid control system that further controls a flow of the technical fluid to other components of a liquid cooling system, such as heat exchangers. For example, a data center may have control over components up to connectors 220, while a customer may have control over components beyond connectors 220. As such, connectors 220 may deliver the technical fluid at a temperature and pressure differential sufficient for the liquid control system and its associated heat loads. The liquid control system may include various components for controlling the flow of the technical fluid to individual cabinets including, but not limited to, manifolds, valves, flow sensors, temperature sensors, pressure sensors, process control units, and the like.

Each of CRAC units 216 and connectors 220 are fluidically coupled to a common supply and return header 213 (“technical fluid header 213”) that supplies technical fluid from and returns technical fluid to technical fluid systems 202. As discussed above, the technical fluid supplied to CRAC units 216 and connectors 220 may be at a uniform temperature and pressure. CRAC units 216 and heat exchangers fluidically coupled to connectors 220 may be associated with a generated heat load. A number and energy consumption of cabinets in data rooms may change over time, such that additional cooling capacity may be required to provide adequate air cooling for groups of cabinets and liquid cooling for individual cabinets. While illustrated in FIG. 2 as supplying technical fluid to CRAC units 216 and connectors 220 in a data hall, technical fluid header 213 may extend to other data halls, may be supplied technical fluid by other technical fluid systems 202, and/or deliver technical fluid to other CRAC units 216 and connectors 220.

To provide cooling capacity for the particular heat load, one or more technical fluid systems 202 are coupled to technical fluid header 213 to supply technical fluid to and return technical fluid from CRAC units 216 and connectors 220. In the example of FIG. 2, data center cooling system 200 includes three modular technical fluid systems 202A, 202B, 202C arranged to provide the particular cooling capacity to various air and liquid cooling systems. For example, each modular technical fluid system 202 may provide a standard unit of cooling capacity, such as 2500 kW. Each technical fluid system 202 may be added or removed as CRAC units 216 and/or connectors 220 are added or removed, and/or as heat loads generated by CRAC units 216 and/or connectors 220 change.

In some examples, technical fluid system 202 may provide segmented cooling capacity that provides resilience to cooling system 200. For example, typical chilled water systems may be relatively large hydraulic systems, such as greater than about 20 megawatts. However, in the event of a leak or failure, such large systems may not bring all or most of the hydraulic system off-line. Rather than provide such a large system, each technical fluid system 202 may a smaller cooling capacity, such as between about 2.5 MW to about 5 MW, that collectively provide a larger cooling capacity. In contrast to a large system, a smaller technical fluid system 202 may only take offline a smaller amount of cooling capacity of system 200.

In the example of FIG. 2, each technical fluid system 202A, 202B, 202C includes a respective cooling tower 208A, 208B, 208C (generically, “cooling tower 208”), a respective cooling fluid circuit 210A, 210B, 210C (“cooling fluid circuit 210”), a respective primary heat exchanger (PHEX) 212A, 212B, 212C (“PHEX 212”), and a respective technical fluid circuit 214A, 214B, 214C (“technical field circuit 214”). Each cooling fluid circuit 210 includes a respective cooling fluid pump 211A, 211B, 211C (“cooling fluid pump 211”).

Each cooling fluid pump 211 is configured to circulate the cooling fluid between PHEX 212 and cooling tower 208. Each technical fluid circuit 214 includes a respective technical fluid pump 215A, 215B, 215B (“technical fluid pump 215”). Each technical fluid pump is configured to circulate the technical fluid between PHEX 212 and technical fluid header 213 for CRAC units 216 and connectors 220. Each primary heat exchanger (PHEX) is configured to transfer heat from the technical fluid to the cooling fluid. Each cooling tower 208 is configured to remove heat from the cooling fluid.

Each cooling tower 208, cooling fluid pump 211, PHEX 212, and technical fluid pump 215 may be configured (e.g., sized) to provide a particular unit of cooling capacity to technical fluid header 213. For example, on a cooling fluid side of technical fluid system 202A, cooling tower 208A, cooling fluid pump 211A, and a first side of PHEX 212A may be configured to handle a particular flow rate of the cooling fluid, such as about 1500 gallons per minute (gpm) of water. On a technical fluid side of technical fluid system 202A, a second side of PHEX 212A and technical fluid pump 215A may be configured to handle a particular flow rate of the technical fluid, such as about 1560 gpm of a water-glycol mixture.

As described above, each technical fluid system 202 is configured to collect heat using the technical fluid, transfer the heat from the technical fluid to the cooling fluid, and discharge the heat to an atmosphere or another system. However, additional functions related to the cooling fluid and/or technical fluid may be handled collectively. In the example of FIG. 2, each of cooling fluid circuits 210A, 210B, 210C are fluidically coupled together through a cooling fluid supply and return header 209 (“cooling fluid header 209”), while each of technical fluid circuits 214A, 214B, 214C are fluidically coupled together through a technical fluid supply and return header 213.

Each of cooling fluid header 209 and technical fluid header 213 is configured to add redundancy and provide a common line for further treating cooling fluid and/or technical fluid. For the cooling fluid, data center cooling system 200 includes a cooling fluid filtration unit 226A and a cooling fluid treatment unit 228A, each fluidically coupled to cooling fluid header 209. Cooling fluid filtration unit 226A is configured to filter the cooling fluid, such as to provide filtration of less or equal to about 25 microns. Cooling fluid treatment unit 228A is configured to maintain a composition of the cooling fluid, such as a concentration of corrosion inhibitors in the cooling fluid. Other functions, such as cooling fluid fill and blowdown, may also be performed through cooling fluid header 209. For the technical fluid, data center cooling system 200 includes a technical fluid filtration unit 226B and a technical fluid treatment unit 228B, each fluidically coupled to technical fluid header 213. Technical fluid filtration unit 226B is configured to filter the technical fluid, such as to provide filtration of less or equal to about 25 microns. Technical fluid treatment unit 228B is configured to determine a composition of the technical fluid, such as a concentration of additives such as corrosion inhibitors in the technical fluid. For example, technical fluid treatment unit 228B may be configured to continuously monitor the technical fluid quality by sampling the technical fluid in technical fluid header 213. In response to the concentration of the additives falling below a setpoint, the additives may be filled, such as through a technical fluid fill. Other functions, such as technical fluid fill and blowdown, may also be performed through technical fluid header 213.

Data center cooling system 200 includes a control system configured to control various components of data center cooling system 200, such as flow rates of spray jets and speeds of fans of cooling towers 208, speeds of cooling fluid pumps 211, speeds of technical fluid pumps 215, filtration parameters of filtration units 226A, 226B, treatment parameters of treatment units 228A, 228B, and any other components that be used to control a temperature and/or pressure of the technical fluid or cooling fluid. The control system includes a variety of sensors, including a temperature sensor 231A and a flow sensor 231B coupled to a supply line of technical fluid header 213. In the example of FIG. 2, the control system includes a controller 230 configured to maintain a temperature and pressure of the technical fluid delivered to CRAC units 216 and connectors 220, such as indicated by temperature sensor 231A and flow sensor 231B, respectively. In some examples, controller 230 may be configured to control an outlet temperature of the technical fluid by controlling a speed of technical fluid pumps 215. For example, rather than control flow of the technical fluid using control valves, which may have a relatively slow response in response to an increase in heat load, technical fluid pumps 215 may be capable of providing a faster change in flow rate of the technical fluid.

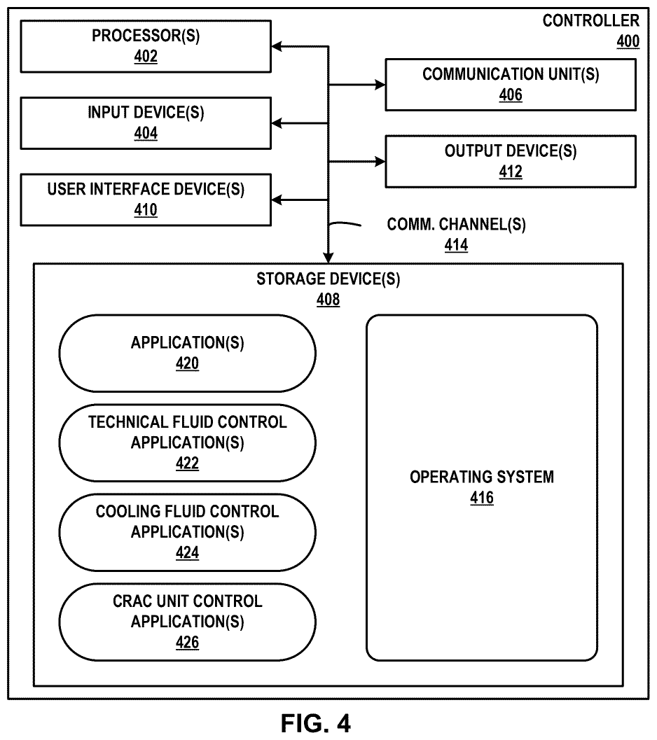

Further operation of controller 230 will be described in FIG. 4 below.

I see that this is described further down in the equipment controls descriptions, but a distinguishing factor of using pump speed to control TF leaving temperature instead of a control valve is the ability to respond rapidly to large load step changes.

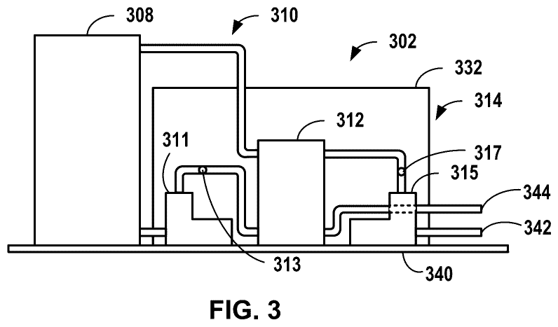

Technical fluid systems described herein may be assembled as a modular unit. FIG. 3 is a conceptual side view diagram illustrating an example modular technical fluid system 302 of a data center cooling system. Technical fluid system 302 includes a cooling tower 308, a cooling fluid circuit 310, a primary heat exchanger (PHEX) 312, and a technical fluid circuit 314. Cooling fluid circuit 310 includes a cooling fluid pump 311 and various piping that couples cooling tower 308 to PHEX 312. Technical fluid circuit 314 include a technical fluid pump 315 and various piping that couples PHEX 312 to a technical fluid header (not shown). For example, a system return line 342 may be configured to couple to a technical fluid return header, and a system supply line 344 may be configured to couple to a technical fluid supply header.

In the example of FIG. 3, each of cooling fluid circuit 310 and technical fluid circuit 314 are each configured to fluidically couple to another respective cooling fluid circuit and technical fluid circuit of another modular technical fluid system. For example, cooling fluid circuit 310 may include a connection 313 configured to couple to another cooling fluid circuit. Similarly, technical fluid circuit 314 may include a connection 317 configured to couple to another technical fluid circuit. While the various piping in cooling fluid circuit 310 and technical fluid circuit 314 are shown as associated with cooling tower 308, cooling fluid pump 311, PHEX 312, and technical fluid pump 315 of technical fluid system 302, in other examples, cooling tower 308, cooling fluid pump 311, PHEX 312, and technical fluid pump 315 are fluidically coupled in parallel with similar components of other technical fluid systems, with piping being commonly shared among the technical fluid systems.

Technical fluid system 302 includes a skid frame 340 configured to support PHEX 312, cooling fluid circuit 310, cooling tower 308, and technical fluid circuit 314. Cooling fluid circuit 310, PHEX 312, and technical fluid circuit 314 may be positioned within an enclosure 332 for protection, while cooling tower 308 may be positioned outside enclosure 332 to discharge heat to an atmosphere.

Data center cooling systems discussed herein may be configured to cool cabinets using a special purpose computing device, such as a controller. FIG. 4 is a block diagram illustrating an example controller 400 configured to control cooling for a data center cooling system, such as controller 230 of FIG. 2. Controller 400 may include a server or other computing device that includes one or more processor(s) 402 for executing technical fluid control application(s) 422 and/or cooling fluid control application(s) 424, although controller 400 may be leveraged for other purposes in data centers as well. Although shown in FIG. 4 as a stand-alone controller 400 for purposes of example, a computing device may be any component or system that includes one or more processors or other suitable computing environment for executing software instructions.

As shown in FIG. 4, controller 400 includes one or more processors 402, one or more input devices 404, one or more communication units 406, one or more output devices 412, one or more storage devices 408, one or more user interface (UI) devices 410, and communication unit 406. Controller 400 includes one or more applications 420, technical fluid control application 422, cooling fluid control application 424, and operating system 416 that are executable by controller 400. Each of components 402, 404, 406, 408, 410, and 412 are coupled operatively for inter-component communications. In some examples, communication channels 414 may include a system bus, a network connection, an inter-process communication data structure, or any other method for communicating data. Communication may be via one or more communication protocols including ModBus, BacNET, proprietary DDC or PLC manufacturer's protocol, PCI, or an open protocol. Controller 400 may be located and execute, for example, within a data center or at another location, such as on a skid associated with a technical fluid system.

Processors 402 may be configured to implement functionality and/or process instructions for execution within controller 400, such as instructions stored in storage device 408. Examples of processors 402 may include, any one or more of a microprocessor, a controller, a digital signal processor (DSP), an application specific integrated circuit (ASIC), a field-programmable gate array (FPGA), or equivalent discrete or integrated logic circuitry.

One or more storage devices 408 may be configured to store information within controller 400 during operation. Storage device 408, in some examples, is described as a (non-transitory) computer-readable storage medium. In some examples, storage device 408 is a temporary memory, meaning that a primary purpose of storage device 408 is not long-term storage. Storage device 408, in some examples, includes volatile memory, meaning that storage device 408 does not maintain stored contents when the computer is turned off. Examples of volatile memories include random access memories (RAM), dynamic random-access memories (DRAM), static random-access memories (SRAM), and other forms of volatile memories known in the art. In some examples, storage device 408 is used to store program instructions for execution by processors 402. Storage device 408 in one example, is used by software or applications running on controller 400 to temporarily store information during program execution. Storage devices 408 may further be configured for long-term storage of information. In some examples, storage devices 408 include non-volatile storage elements. Examples of such non-volatile storage elements include magnetic hard discs, optical discs, floppy disks, Flash memories, or forms of electrically programmable memories (EPROM) or electrically erasable and programmable (EEPROM) memories.

Controller 400, in some examples, also includes one or more communication units 406. Controller 400, in one example, utilizes communication units 406 to communicate with external devices via one or more networks, such as one or more wired/wireless/mobile networks, etc. Communication units 406 may include a network interface card, such as an Ethernet card, an optical transceiver, a radio frequency transceiver, or any other type of device that can send and receive information. Other examples of such network interfaces may include 3G, 4G and Wi-Fi radios.

In some examples, controller 400 may use communication unit 406 to communicate with one or more devices of a data center cooling system, such as data center cooling systems 100 of FIG. 1 or 200 of FIG. 2, or of a technical fluid system, such as technical fluid systems 102 of FIGS. 1, 202 of FIG. 2, or 302 of FIG. 3, configured to provide cooling to cabinets of a data center. For example, communication unit 406 may be communicatively coupled to fans and sprayers of cooling tower 208, cooling fluid pump 211, technical fluid pump 215, and fans and refrigeration components of CRAC units 216, and configured to receive measurements from components of technical fluid system 202 and send control signals to components of technical fluid system 202. For example, communication unit 406 may receive technical fluid temperature measurements from temperature sensor 231A and technical fluid flow rate measurements from flow sensor 231B. As another example, communication unit 406 may send control signals to control valves of CRAC units 216 to control the flow rate of technical fluid to condensers, send control signals to fans of CRAC units 216 to control a flow rate of supply air; and the like.

In some examples, controller 400 may use communication unit 406 to communicate with an external device, such as a controller for a liquid cooling system, a data transfer system and/or an electrical power system. In some examples, communication unit(s) 406 and input device(s) 404 may be operatively coupled to controller 400. For example, controller 400 may receive a communication from an analog input device indicating an amperage, voltage, or other signal at the input device. Depending on implementation, digital signaling techniques, analog signaling techniques, or any combination thereof, may be used by controller 400 for the purpose of controlling a temperature and/or pressure of the technical fluid delivered to air and liquid cooling systems, in accordance with the disclosure.

Controller 400 may include one or more user interface devices 410 and/or one or more output devices 412. User interface devices 410 may be configured to receive input from a user through tactile, audio, or video feedback. Examples of user interface devices(s) 410 include a presence-sensitive display, a mouse, a keyboard, a voice responsive system, video camera, microphone or any other type of device for detecting a command from a user. In some examples, a presence-sensitive display includes a touch-sensitive screen. Output device 412, may be configured to provide output to a user using tactile, audio, or video stimuli. Output device 412, in one example, includes a presence-sensitive display, a sound card, a video graphics adapter card, or any other type of device for converting a signal into an appropriate form understandable to humans or machines. Additional examples of output device 412 include a speaker, a liquid crystal display (LCD), or any other type of device that can generate intelligible output to a user.

Controller 400 may include operating system 416. Operating system 416, in some examples, controls the operation of components of controller 400. For example, operating system 416, in one example, facilitates the communication of one or more applications 420, technical fluid control application 422, and cooling fluid control application 424 with processors 402, communication unit 406, storage device 408, input device 404, user interface devices 410, and output device 412.

Application 420, technical fluid control application 422, cooling fluid control application 424, and CRAC unit control application 426 may also include program instructions and/or data that are executable by controller 400. Technical fluid control application 422, cooling fluid control application 424, and CRAC unit control application 426 may include instructions for causing a special-purpose computing device to perform one or more of the operations and actions described in the present disclosure with respect to controller 400, such as illustrated in the various examples below with respect to data center cooling system 100 of FIG. 1.

As one example, CRAC unit control application 426 may include instructions that cause processor(s) 402 of controller 400 to control CRAC unit 116 to discharge supply air at particular conditions, such as temperature and flow rate. For example, CRAC unit control application 426 may control a refrigeration cycle of CRAC unit 116 by regulating a pressure and flow of the refrigerant using the compressor and expansion valve and regulating a flow rate of the technical fluid through the condenser, and control a flow rate of the supply air by adjusting the speed of fans. CRAC unit control application 426 may receive various measurements, such as air temperature entering and exiting CRAC unit 116, technical fluid temperature entering and exiting the condenser, technical fluid flow rate, and refrigerant pressure and temperature at various points in the refrigeration cycle. CRAC unit control application 426 may control CRAC unit 116 according to various setpoints, such as a supply air temperature setpoint. In operation, CRAC unit control application 426 may adjust the fan speed to control the amount of air passing over the evaporator coil, adjust the flow rate of the technical fluid to ensure effective condensation of the refrigerant, and adjust the operation of the compressor and expansion valve to maintain the desired refrigerant pressure and temperature.

As another example, technical fluid control application 422 may include instructions that cause processor(s) 402 of controller 400 to control technical fluid circuit 114 to circulate technical fluid at particular conditions, such as temperature and flow rate. For example, technical fluid control application 422 may control a technical fluid pump of technical fluid circuit 114 by regulating a speed of the technical fluid pump to increase or decrease a flow rate such that the flow rate of the technical fluid matches the heat load. Technical fluid control application 422 may receive various measurements, such as technical fluid temperature exiting technical fluid circuit 114 and a flow rate of the technical fluid.

Technical fluid control application 422 may control technical fluid circuit 114 according to various setpoints, such as the technical fluid temperature setpoint at the supply line and a differential pressure setpoint of the technical fluid between the supply and return technical fluid headers. In operation, technical fluid control application 422 may monitor temperature, flow rate, and pressure measurements, and adjust the pump speed to maintain an adequate temperature of the technical fluid.

As another example, cooling fluid control application 424 may include instructions that cause processor(s) 402 of controller 400 to control heat rejection unit 108 and cooling fluid circuit 110 to circulate cooling fluid at particular conditions, such as temperature and flow rate. For example, cooling fluid control application 424 may control a cooling fluid pump of cooling fluid circuit 110 and various components of heat rejection unit 108 by regulating a speed of the cooling fluid pump to increase or decrease a flow rate and regulating a rate of cooling of heat rejection unit 108 (e.g., a speed of fans of a cooling tower). Cooling fluid control application 424 may receive various measurements, such as cooling fluid temperature exiting PHEX 112 and heat rejection unit 108 and technical fluid temperature exiting PHEX 112. Cooling fluid control application 424 may control cooling fluid circuit 110 and heat rejection unit 108 according to various setpoints, such as the technical fluid setpoint at the exit of PHEX 112. In operation, cooling fluid control application 424 may adjust the speed of fans in heat rejection unit 108 (e.g., cooling tower) and adjust the speed of the cooling fluid pump to adjust the temperature of the cooling fluid.

While controller 400 has been described with respect to a single technical fluid system, controller 400 may be configured to control two or more technical fluid systems. For example, multiple heat rejection units, cooling fluid pumps, and technical fluid pump may be controlled based on setpoints for the temperature of the technical fluid, such that controller 400 controls the technical fluid systems to deliver the technical fluid at the target temperature and flow rate.

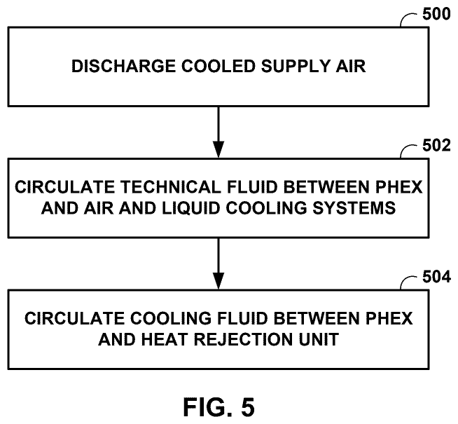

FIG. 5 is a flow diagram of an example technique for cooling cabinets of a data hall using a data center cooling system. The method of FIG. 5 includes discharging, by CRAC units of an air cooling system, cooled supply air. For example, CRAC unit control application 426 may control one or more CRAC units 116 to discharge cooled supply air at a particular temperature and flow rate. Heat absorbed from the supply air by a refrigerant in CRAC units 116 may be removed from the refrigerant by a technical fluid.

The method of FIG. 5 includes delivering, by one or more technical fluid systems 102, the technical fluid to one or more server heat exchangers (SHEX) 124 of liquid cooling system 106 and one or more CRAC units 116 of air cooling system 104. This delivery includes circulating, by one or more technical fluid pumps of technical fluid circuit 114, the technical fluid between PHEX 112 and each of liquid cooling system 106 and air cooling system 104 to absorb heat from SHEXs 124 and CRAC units 116 (502). For example, technical fluid control application 422 may control a technical fluid pump to discharge the technical fluid at a particular flow rate. The delivery further includes circulating, by one or more cooling fluid pumps of cooling fluid circuit 110, a cooling fluid between PHEX 112 and heat rejection unit 108 to transfer heat from the technical fluid to the cooling fluid and remove the heat from the cooling fluid (504). For example, cooling fluid control application 424 may control a cooling fluid pump to discharge the cooling fluid at a particular flow rate.

The techniques described throughout may be implemented by or as any one of a method, a device and a system according to the principles of the present disclosure. In addition, the techniques described throughout may be implemented in hardware, software, firmware, or any combination thereof. Various features described as modules, units or components may be implemented together in an integrated logic device or separately as discrete but interoperable logic devices or other hardware devices. In some cases, various features of electronic circuitry may be implemented as one or more integrated circuit devices, such as an integrated circuit chip or chipset.

If implemented in hardware, this disclosure may be directed to an apparatus such as a processor or an integrated circuit device, such as an integrated circuit chip or chipset. Alternatively or additionally, if implemented in software or firmware, the techniques may be realized at least in part by a computer readable data storage medium comprising instructions that, when executed, cause a processor to perform one or more of the methods described above. For example, the computer-readable data storage medium may store such instructions for execution by a processor.

A computer-readable medium may form part of a computer program product, which may include packaging materials. A computer-readable medium may comprise a computer data storage medium such as random-access memory (RAM), read-only memory (ROM), non-volatile random-access memory (NVRAM), electrically erasable programmable read-only memory (EEPROM), flash memory, magnetic or optical data storage media, and the like. In some examples, an article of manufacture may comprise one or more computer-readable storage media. In some examples, the computer-readable storage media may comprise non-transitory media. The term “non-transitory” may indicate that the storage medium is not embodied in a carrier wave or a propagated signal. In certain examples, a non-transitory storage medium may store data that can, over time, change (e.g., in RAM or cache).

The code or instructions may be software and/or firmware executed by processing circuitry including one or more processors, such as one or more digital signal processors (DSPs), general purpose microprocessors, application-specific integrated circuits (ASICs), field-programmable gate arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, functionality described in this disclosure may be provided within software modules or hardware modules.

Example 1: A technical fluid system includes a technical fluid circuit comprising one or more technical fluid pumps configured to deliver a technical fluid to a liquid cooling system and an air cooling system; a primary heat exchanger (PHEX) configured to transfer heat from the technical fluid to a cooling fluid; a heat rejection unit configured to remove heat from the cooling fluid; and a cooling fluid circuit comprising one or more cooling fluid pumps configured to circulate the cooling fluid between the PHEX and the heat rejection unit.

Example 2: The technical fluid system of example 1, wherein the heat rejection unit comprises a cooling tower.

Example 3: The technical fluid system of any of examples 1 and 2, wherein the technical fluid system is a modular technical fluid system, and wherein the cooling fluid circuit and the technical fluid circuit are each configured to fluidically couple to another respective cooling fluid circuit and technical fluid circuit of another modular technical fluid system.

Example 4: The technical fluid system of example 3, further comprising a skid frame configured to support the PHEX, the cooling fluid circuit, the heat rejection unit, and the technical fluid circuit.

Example 5: The technical fluid system of example 4, further comprises a technical fluid filtration unit; and a technical fluid treatment unit.

Example 6: The technical fluid system of example 5, wherein the technical fluid filtration unit is configured to provide filtration of less than or equal to 25 micron, and wherein the technical fluid treatment system is configured to maintain a corrosion inhibitor in the technical fluid.

Example 7: The technical fluid system of any of examples 1 through 6, wherein the technical fluid system has a cooling capacity of at least 2500 kilowatts (kW).

Example 8: The technical fluid system of any of examples 1 through 7, wherein the technical fluid comprises a mixture of water and glycol, and wherein the cooling fluid comprises water.

Example 9: A data center cooling system includes a liquid cooling system includes a technical fluid circuit comprising one or more technical fluid pumps configured to deliver a technical fluid to the liquid cooling system and the air cooling system; a primary heat exchanger (PHEX) configured to transfer heat from the technical fluid to a cooling fluid; a heat rejection unit configured to remove heat from the cooling fluid; and a cooling fluid circuit comprising one or more cooling fluid pumps configured to circulate the cooling fluid between the PHEX and the heat rejection unit.

Example 10: The data center cooling system of example 9, wherein the one or more technical fluid systems comprises two or more technical fluid systems.

Example 11: The data center cooling system of example 10, further comprising a technical fluid header configured to fluidically couple the liquid cooling system and the air cooling system to the two or more technical fluid systems.

Example 12: The data center cooling system of example 11, further comprises: a technical fluid filtration unit fluidically coupled to the technical fluid header; and a technical fluid treatment unit fluidically coupled to the technical fluid header.

Example 13: The data center cooling system of any of examples 10 through 12, further comprising a cooling fluid header configured to fluidically couple the cooling fluid circuits of each of the two or more technical fluid systems.

Example 14: The data center cooling system of any of examples 12 and 13, further comprises: a cooling fluid filtration unit fluidically coupled to the cooling fluid header; and a cooling fluid treatment unit fluidically coupled to the cooling fluid header.

Example 15: A method for cooling cabinets of a data center includes delivering, by one or more technical fluid systems, a technical fluid to one or more server heat exchangers (SHEX) of a liquid cooling system and one or more computer room air conditioning (CRAC) units of an air cooling system, by at least, for each technical fluid system: circulating, by one or more technical fluid pumps of a technical fluid circuit, the technical fluid between a primary heat exchanger (PHEX) and each of the liquid cooling system and the air cooling system to absorb heat from the one or more SHEXs and the one or more CRAC units; and circulating, by one or more cooling fluid pumps of a cooling fluid circuit, a cooling fluid between the PHEX and a heat rejection unit to transfer heat from the technical fluid to the cooling fluid and remove the heat from the cooling fluid.

Example 16: The method of example 15, further comprising discharging, by the one or more CRAC units, cooled supply air.

Example 17: The method of any of examples 15 and 16, wherein the one or more technical fluid systems comprises two or more technical fluid systems.

Example 18: The method of example 17, wherein the liquid cooling system and the air cooling system are fluidically coupled to the two or more technical fluid systems via a technical fluid header.

Example 19: The method of any of examples 17 and 18, wherein the cooling fluid circuits of each of the two or more technical fluid systems are fluidically coupled via a cooling fluid header.

Example 20: The method of any of examples 15 through 19, wherein the technical fluid comprises a mixture of water and glycol, and wherein the cooling fluid comprises water.

What is claimed is:

1. A technical fluid system, comprising:
a technical fluid circuit comprising one or more technical fluid pumps configured to deliver a technical fluid to a liquid cooling system and an air cooling system;
a primary heat exchanger (PHEX) configured to transfer heat from the technical fluid to a cooling fluid;
a heat rejection unit configured to remove heat from the cooling fluid; and
a cooling fluid circuit comprising one or more cooling fluid pumps configured to circulate the cooling fluid between the PHEX and the heat rejection unit.

2. The technical fluid system of claim 1, wherein the heat rejection unit comprises a cooling tower.

3. The technical fluid system of claim 1,
wherein the technical fluid system is a modular technical fluid system, and
wherein the cooling fluid circuit and the technical fluid circuit are each configured to fluidically couple to another respective cooling fluid circuit and technical fluid circuit of another modular technical fluid system.

4. The technical fluid system of claim 3, further comprising a skid frame configured to support the PHEX, the cooling fluid circuit, the heat rejection unit, and the technical fluid circuit.

5. The technical fluid system of claim 4, further comprises
a technical fluid filtration unit; and
a technical fluid treatment unit.

6. The technical fluid system of claim 5,
wherein the technical fluid filtration unit is configured to provide filtration of less than or equal to 25 micron, and
wherein the technical fluid treatment system is configured to maintain a corrosion inhibitor in the technical fluid.

7. The technical fluid system of claim 1, wherein the technical fluid system has a cooling capacity of at least 2500 kilowatts (kW).

8. The technical fluid system of claim 1,
wherein the technical fluid comprises a mixture of water and glycol, and
wherein the cooling fluid comprises water.

9. A data center cooling system, comprising:
a liquid cooling system comprising one or more liquid cooling connectors configured to fluidically couple to a server heat exchanger (SHEX) of a cabinet;
an air cooling system comprising one or more computer room air conditioning (CRAC) units configured to cool supply air; and
one or more technical fluid systems fluidically coupled to the liquid cooling system and the air cooling system, wherein each technical fluid system comprises:
a technical fluid circuit comprising one or more technical fluid pumps configured to deliver a technical fluid to the liquid cooling system and the air cooling system;
a primary heat exchanger (PHEX) configured to transfer heat from the technical fluid to a cooling fluid;
a heat rejection unit configured to remove heat from the cooling fluid; and
a cooling fluid circuit comprising one or more cooling fluid pumps configured to circulate the cooling fluid between the PHEX and the heat rejection unit.

10. The data center cooling system of claim 9, wherein the one or more technical fluid systems comprises two or more technical fluid systems.

11. The data center cooling system of claim 10, further comprising a technical fluid header configured to fluidically couple the liquid cooling system and the air cooling system to the two or more technical fluid systems.

12. The data center cooling system of claim 11, further comprises:
a technical fluid filtration unit fluidically coupled to the technical fluid header; and
a technical fluid treatment unit fluidically coupled to the technical fluid header.

13. The data center cooling system of claim 10, further comprising a cooling fluid header configured to fluidically couple the cooling fluid circuits of each of the two or more technical fluid systems.

14. The data center cooling system of claim 13, further comprises:
a cooling fluid filtration unit fluidically coupled to the cooling fluid header; and
a cooling fluid treatment unit fluidically coupled to the cooling fluid header.

15. A method for cooling cabinets of a data center, comprising:
delivering, by one or more technical fluid systems, a technical fluid to one or more server heat exchangers (SHEX) of a liquid cooling system and one or more computer room air conditioning (CRAC) units of an air cooling system, by at least, for each technical fluid system:
circulating, by one or more technical fluid pumps of a technical fluid circuit, the technical fluid between a primary heat exchanger (PHEX) and each of the liquid cooling system and the air cooling system to absorb heat from the one or more SHEXs and the one or more CRAC units; and
circulating, by one or more cooling fluid pumps of a cooling fluid circuit, a cooling fluid between the PHEX and a heat rejection unit to transfer heat from the technical fluid to the cooling fluid and remove the heat from the cooling fluid.

16. The method of claim 15, further comprising discharging, by the one or more CRAC units, cooled supply air.

17. The method of claim 15, wherein the one or more technical fluid systems comprises two or more technical fluid systems.

18. The method of claim 17, wherein the liquid cooling system and the air cooling system are fluidically coupled to the two or more technical fluid systems via a technical fluid header.

19. The method of claim 17, wherein the cooling fluid circuits of each of the two or more technical fluid systems are fluidically coupled via a cooling fluid header.

20. The method of claim 15,
wherein the technical fluid comprises a mixture of water and glycol, and
wherein the cooling fluid comprises water.
